(19) United States
(12) Patent Application Publication
(10) Pub. No.: US 2026/0288066 A1
(43) Pub. Date: Sep. 24, 2026

(54) COLOURED TIMEPIECE COMPONENT

(71) Applicant: ROLEX SA, Geneva (CH)

(72) Inventor: Alexandre Fête, Bernex (CH)

(73) Assignee: ROLEX SA, Geneva (CH)

(21) Appl. No.: 19/490,049

(22) PCT Filed: Jun. 4, 2024
(86) PCT No.: PCT/EP2024/065272

§ 371 Date: Dec. 4, 2025

(30) Foreign Application Priority Data
Jun. 5, 2023 (EP) 23177178.3

(51) Int. Cl. G04B 19/10; G04B 19/12; G04D 3/00

(52) U.S. Cl. CPC G04B 19/10; G04B 19/12; G04D 3/0092

(57) ABSTRACT

The timepiece component, in particular an external timepiece component, in particular a dial, has a body, one surface of which is at least partially covered by a coating forming an optical colouring device, the coating including a stack of the following successive layers on the surface:—a first layer made of at least one metal material; —a second layer of semiconductor material; —a third layer made of at least one metal material; —optionally repetition of the second and third layers; —one or more oxide layers; —optionally an upper finishing layer such as an acrylic and/or nitrocellulose finishing layer, in particular a layer of zapon; —optionally, one or more layers of a metal material, in particular chromium, or titanium, inserted between two of the layers of the coating defined above, such a layer promoting adhesion and/or partial absorption of light.

The invention relates to a timepiece component comprising a coating that forms an optical device for coloring or, more generally, decorating the timepiece component. It also relates to a timepiece comprising at least one such timepiece component. It also relates to a process for producing such a timepiece component.

There exist old and traditional processes for coloring timepiece components, for example by depositing paint, varnish, lacquer or enamel.

Novel techniques involving the deposition of thin layers are now used as an alternative, as described for example in documents EP3896193A1 and EP4060386A1. These solutions are based on the deposition of a coating comprising a number of thin layers that make it possible to obtain different colors. However, these existing processes have drawbacks, inter alia their complexity and the difficulty of obtaining a repeatable and robust color in a manner suitable for industrial production.

The general object of the invention is to provide a solution for coloring a timepiece component that makes it possible to improve existing solutions.

More precisely, a first object of the invention is to provide a solution for coloring a timepiece component that makes it possible to achieve a predefined color in a durable, robust, and repeatable manner.

A second object of the invention is to provide a solution for coloring a timepiece component by a simple process compatible with industrial production.

To this end, the invention is based on a timepiece component, especially an exterior timepiece component, especially a dial, wherein it comprises a body, one surface of which is at least partially covered with a coating forming an optical coloring device, wherein said coating comprises a stack of the following successive layers on said surface:
a first layer made of at least one metallic material;
a second layer of semiconductor material;
a third layer made of at least one metallic material;
optionally repeating the second and third layers;
one or more oxide layers;
optionally an upper finishing layer such as an acrylic and/or nitrocellulose finishing layer, especially a layer of zapon;
optionally, one or more layers of a metallic material, especially chromium or titanium, interposed between two of said layers of the coating defined above, such a layer promoting adhesion and/or partial absorption of light.

The invention also relates to a process for producing a timepiece component, especially an exterior timepiece component, especially a dial, comprising a prior step of producing a body of the timepiece component, wherein said process comprises depositing a coating onto at least part of a surface of said body, this depositing of a coating comprising the following steps:
depositing a first layer made of at least one metallic material;
depositing a second layer of semiconductor material;
depositing a third layer made of at least one metallic material;
optionally repeating the depositing of the second and third layers;
depositing one or more oxide layers;
optionally depositing an upper finishing layer such as an acrylic and/or nitrocellulose finishing layer, especially a layer of zapon;
optionally depositing one or more layers of a metallic material, especially chromium or titanium, interposed between two of said layers of the coating defined above, such a layer of chromium and/or titanium having a very small thickness of less than or equal to 2 nm so as to promote adhesion of said two coating layers, or such a layer of chromium and/or titanium having a thickness greater than 2 nm so as to form a layer of partial absorption.

The invention is defined more precisely by the claims.

These objects, features, and advantages of the present invention will be set out in detail in the description that follows of particular embodiments, given by way of non-limiting example with reference to the appended figures, in which:

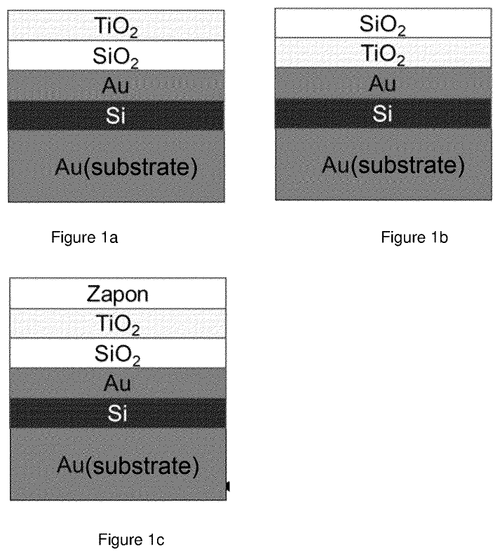

FIGS. 1a, 1b, and 1c schematically represent sectional views of coatings for a component according to three alternatives of a first embodiment of the invention.

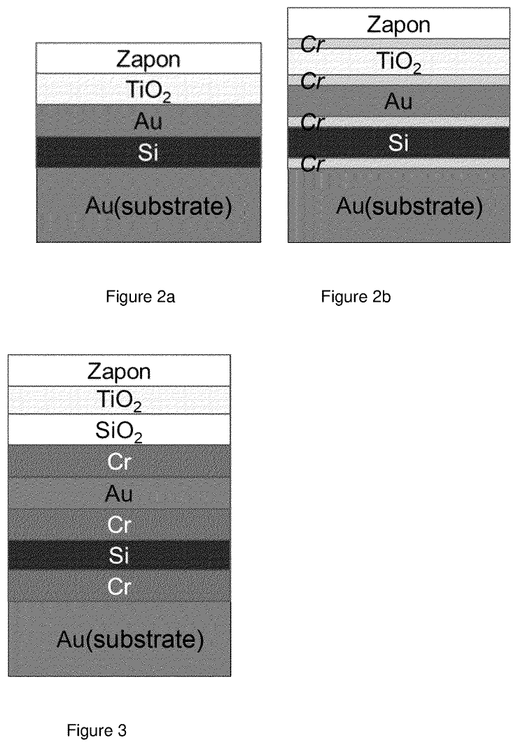

FIGS. 2a and 2b schematically represent sectional views of coatings for a component according to two alternatives of a second embodiment of the invention.

FIG. 3 schematically represents a sectional view of a coating for a component according to a third embodiment of the invention.

By way of convention, the adjectives “upper” and “lower”, “top” and “bottom”, and the expressions “above” and “below” will be used throughout the description in accordance with the orientations used in the figures. In these figures, the bottommost layer is the one intended to be applied in direct contact with the surface of the body of a timepiece component and the topmost layer is the one facing outwards that forms the final outer surface of the timepiece component.

The simplified term “component” will be used hereinafter to denote a timepiece component.

The aim of the invention is therefore to generate a chosen color of a surface of a component. The invention is based on the use of a coating comprising several specific overlaid thin layers that together form an optical device the effect of which is a coloration, i.e. the effect consists of modulating the reflectivity behavior of light at a surface in order to favor certain wavelengths over others.

The purpose of this effect is of course to permit a user to perceive a predefined color and/or more generally a decorative effect. This effect therefore occurs in the visible range of light. The visible range will hereinafter refer to all visible wavelengths or a significant part of the visible wavelengths. Thus, the expression “visible range” may for example hereinafter mean a wavelength range of between 380 and 780 nm, or even between 380 and 650 nm, or even between 380 and 550 nm. The term “visible range” may improperly denote only part of the theoretical visible range.

As will be detailed hereinbelow, the optical effect according to the concept of the invention is obtained by a stack of thin layers having chosen optical properties. The overall optical effect results from the different absorption, reflection, and interference phenomena induced by the overlaid layers. In particular, the material chosen for each layer and the associated refractive index will make it possible to define the optical property that is sought for each layer and an overall optical effect resulting from the combination of the different layers.

The refractive index is commonly a complex number that consists, as is known, of a real part n, which defines the deviation of an incident ray of light due to an interface between two given layers, and an imaginary part k, which defines an extinction coefficient that is a measure of the attenuation of the incident light wave. These values depend on the wavelength, and the refractive indices will accordingly hereinafter be considered to be in the visible range.

In addition, the expression “based on a material” will be used to denote the use of at least 50% by weight of said material.

As mentioned above, the invention is based on the use of a specific coating that forms an optical coloring device that is arranged on all or part of a surface of a body of a component to be colored.

More particularly, the invention is based on the use of a specific coating that comprises a first group comprising at least two reflective layers surrounding a layer of semiconductor material and a second group comprising at least one oxide layer.

The first group of the coating comprises, in the following order from bottom to top:
a first layer made of one or more metallic materials;
a second layer of semiconductor material;
a third layer made of one or more metallic materials.

The first and third layers thus form reflective layers, i.e. their principal effect is to reflect incident light. The first and third layers, and even the other optional reflective layers of the coating, preferably have the characteristic feature of forming a medium for which the refractive index in the visible range comprises a real part of less than 3.5 and an imaginary part, i.e. an extinction coefficient, of greater than 1. This real part can have a maximum value (less than 3.5) in the visible range and form a function of the wavelength that initially increases up to this maximum value and then decreases with increasing wavelength. The imaginary part can increase with the wavelength.

These layers are also preferably made up of one or more metallic materials. Each of these layers may be composed entirely of just one metallic material or even of a mixture of two or more metallic materials arranged within the same layer or in a succession of overlaid layers. According to advantageous embodiments, the metallic material(s) is/are chosen from gold, platinum, titanium, palladium, chromium, rhodium, silver, copper, tungsten, and aluminum, it being possible for the latter to be encapsulated in a very thin layer of Al₂O₃ deposited by an ALD (atomic layer deposition) process. Alternatively, any metallic material may be used. According to a simple embodiment, the first and third layers may each take the form of a metal layer composed entirely of just one metallic material, which may be the same for the two layers or may be different.

In addition, according to one embodiment, the first layer has a thickness greater than or equal to 100 nm. Said layer optically isolates the coating from the body. It also makes a large contribution to the overall optical rendering of the coating. This first layer is thicker than the other layers of the coating, and can act as a substrate, while at the same time being an element of the coating. Alternatively, this first layer may be formed by the body.

According to one embodiment, the third layer has a thickness of between 2 and 50 nm, or even between 5 and 50 nm, or even between 30 and 40 nm, and/or a thickness greater than or equal to 20 nm.

As implementation examples, the third layer can be chosen from:
a layer of gold having a thickness of between 5 and 50 nm, or even between 30 and 40 nm, and/or having a thickness greater than or equal to 20 nm, or
a layer of platinum, of titanium, of palladium, of chromium, of rhodium or of silver of between 5 and 50 nm, or even between 30 and 40 nm, and/or having a thickness greater than or equal to 20 nm, or
a layer comprising gold and/or platinum and/or titanium and/or palladium and/or chromium and/or rhodium and/or silver of between 5 and 50 nm, or even between 30 and 40 nm, and/or having a thickness greater than or equal to 20 nm.

According to an advantageous embodiment, gold is used as a metal layer for the first and/or third layer, optionally combined with chromium, as will be detailed hereinbelow. This is because gold is a robust material that is easy to deposit and shows good reproducibility from one production cycle to the next.

Advantageously, the second layer of semiconductor material has the characteristic feature of forming a medium for which the refractive index in the visible range comprises a real part of greater than 2.5 and an imaginary part, i.e. an extinction coefficient, of greater than 0.05. This real part can have a maximum value (greater than 2.5) in the visible range and form a function of the wavelength that initially increases up to this maximum value and then decreases with increasing wavelength. The imaginary part can decrease with the wavelength. The extinction coefficient is in particular greater than 0.05 for wavelengths below 550 nm, or even for wavelengths between 380 and 550 nm, or even between 380 and 650 nm, or even between 380 and 780 nm.

The second layer is based on one or more semiconductor materials. It may be composed entirely of just one semiconductor material or even of a mixture of two or more semiconductor materials arranged within the same layer or of two overlaid layers. According to advantageous embodiments, the semiconductor material(s) is/are chosen from silicon Si, germanium Ge, a combination of silicon Si and germanium Ge, and a III-V family semiconductor material such as gallium arsenide GaAs or tantalum oxynitride (TaOₓN_{y}). It should be noted that the latter material may be alternately insulating, semiconducting or electrically conducting, according to its degree of nitridation and oxidation, respectively characterized by the values of y and x. This implies that its refractive index can vary over a wide range of values. It is possible to form layers in this TaOₓN_{y} material showing optical behavior similar to that of a semiconductor, or even similar to that of silicon Si. Alternatively, any semiconductor material may be used, advantageously one having an extinction coefficient greater than 0.05.

According to an advantageous embodiment, the second layer has a thickness of between 5 and 50 nm.

The use of silicon, and more generally of a semiconductor material, offers several advantages. The optical behavior of the second layer varies little with the angle of incidence, which is not the case with silicon oxide, for example. This is because the refractive index of semiconductor materials being generally high (real part greater than 2.5, or even 3, in the visible range), the trajectory of light rays is naturally brought back to the vertical when they penetrate the material. In addition, the non-zero imaginary part of the refractive index of these materials implies that interfaces play an important role in the optical interference phenomenon. This makes it possible in particular to strongly limit the iridescence of the color obtained.

It should be noted that the semiconductor material used is not oxidized, and at least not intentionally oxidized. Similarly, this semiconductor material is not intentionally amorphous and is not hydrogenated.

The structure of this first group of the coating, comprising the use of two layers of metal surrounding a layer of semiconductor material, is advantageous, since it makes it possible to modulate the amount of light that is transmitted and reflected and in particular the intensity of light that interacts with the layer of semiconductor material. Moreover, the thickness of the third metal layer can be chosen so as to decouple the layer of semiconductor material of the second group of the coating. Indeed, even for a relatively transparent metal such as gold in small thicknesses, a thickness of about 20 nm is already sufficient to attenuate electromagnetic radiation significantly. The third layer thus makes it possible to determine the amount of light that reaches the layer of semiconductor material.

Finally, the inventors have discovered, surprisingly, that this combination of said first group has very advantageous properties that make it possible to modulate the optical properties over the entire visible range in a flexible, robust, and reproducible manner, without iridescence. The result cannot be obtained from the layers taken individually.

This first group can thus be based on a multitude of combinations of materials, for example Au(substrate)/Si/Au, Au(substrate)/Si/Ag, Ag(substrate)/Si/Au, Rh(substrate)/Si/Au, (Rh/Au)(substrate)/Si/Au, Cr(substrate)/Si/Au, etc.

Optionally, this structure of the first group can be modified to incorporate one or more layers of chromium Cr, or of metal more generally, in particular interposed between two of the three layers described above. Such a layer of chromium can perform two different functions.

A layer of chromium, or of metal more generally, of small thickness, of less than 2 nm, advantageously between 0.5 and 2 nm, has little optical effect, and mainly performs the function of an adhesion layer. It can be interposed between any two layers of the coating to improve their adhesion.

A layer of chromium, or of metal more generally, of greater thickness, of greater than 2 nm, additionally participates in the optical effect of the coating. In particular, it performs a function of partial absorption of incident light. It may be associated with the first layer or with the third layer, as mentioned above. This makes it possible, for example, to modify the reflection at the interface between the layer of semiconductor material and the third layer in a controlled and versatile manner. Such a layer may be present interposed between two layers of the first group or may be positioned on top of the first group, so as to form an interface with a second group of the coating, described hereinbelow.

Alternatively, any metal can be used in place of the chromium, depending on the desired effect, such as for example titanium Ti, which can perform the functions of an adhesion layer and/or of a partial absorption layer.

The first group of the coating can thus have a structure enhanced by the presence of one or more layers of metal, such as chromium. Its structure can thus consist for example of combinations such as Au(substrate)/Si/Cr—Au—Cr, Au(substrate)/Si/Au—Cr, Au(substrate)/Si/Cr—Au, Au(substrate)-Cr/Si/Au, Au(substrate)-Cr/Si/Cr—Au, Au(substrate)-Cr/Si/Cr—Au—Cr, Au(substrate)-Cr/Si/Au—Cr, or even Au(substrate)/Si/Cr, the layer of chromium here forming the abovementioned third layer.

As a further alternative, instead of a sequential combination of layers involving a layer of chromium such as Cr—Au—Cr, it is also possible to deposit an AuₓCr_{y} mixed layer by co-depositing two different materials at the same time onto the same area. The Cr—Au—Cr sequential iteration is simpler and more robust to implement in practice and remains the preferred embodiment.

According to an alternative realization, the structure formed by the first group could be repeated, i.e. the first group could comprise the additional overlaying of a layer of semiconductor material and of a reflective layer according to a structure in which a layer of semiconductor material alternates with a reflective layer, each layer of semiconductor material being interposed between two reflective layers.

In addition, the coating comprises a second group that is positioned on the first group described above. This second group comprises at least one oxide layer. This second group makes it possible in particular to modulate the reflectivity of the coating, and for example to increase the perceived brightness of the surface.

The refractive index in the visible range of each of these oxide layers preferably comprises a real part of less than 3 and an imaginary part of less than 0.05, or even less than 0.01.

According to one embodiment, said one or more oxide layers of this second group comprises two layers respectively composed of two different materials, the refractive indices of which are different.

According to one embodiment, each of the oxide layers of this second group consists of or is based on a material chosen from SiO₂, TiO₂, Al₂O₃, Si₃N₄, Ta₂O₅, TaOₓN_{y}, AlOₓN_{y}, and TiOₓN_{y}. In the case of the latter ternary materials, the chosen stoichiometry will be such that the material has optical properties similar to those of the other oxides.

According to one embodiment, the second group consists of:
a layer of silicon oxide SiO₂ having a thickness of between 20 and 140 nm, preferably between 40 and 75 nm, and/or
a layer of titanium oxide TiO₂ having a thickness of between 5 and 100 nm, preferably between 5 and 50 nm.

In all cases, the thicknesses of the oxide layers are minimized and small, so as to minimize the iridescence that they produce and to have good industrial robustness.

This second group, in addition to contributing to the definition of the optical properties of the coating, also makes it possible to form a protective layer of the coating and thus to increase the environmental robustness of the stack of coating layers.

Lastly, the second group optionally comprises an upper finishing layer, such as an acrylic and/or nitrocellulose layer, especially a layer of zapon, which is therefore positioned on the oxide layer(s). Alternatively, this finishing layer may comprise another material, such as a sol-gel type material. This finishing layer may also comprise functional compounds such as a colorant or diffusing particles. It should be noted that in such a case of using a finishing layer, such as an acrylic and/or nitrocellulose layer, especially a layer of zapon, it is advantageous to deposit a final layer of metal, especially chromium, having a thickness of less than 2 nm, and preferably greater than 0.5 nm, onto the last oxide layer, i.e. the topmost layer, so as to form an adhesion layer of the finishing layer. It has indeed been noted that such a layer strengthens the adhesion of the acrylic and/or nitrocellulose finishing layer to the structure very significantly.

A further point to note is that, if an acrylic and/or nitrocellulose finishing layer is used, consideration is also given to its optical properties. Specifically, certain products used for such a finishing layer, for example “zapon”, have a refractive index close to that of SiO₂ oxide. In this case, it may be favorable not to deposit a layer of SiO₂ oxide, since the optical effect of the latter may be masked to a substantial degree by the effect of the finishing layer.

The second group preferably does not comprise a metal layer producing an optical effect. It is possible to employ just a thin metal layer, for example a layer of chromium and/or titanium, having a thickness of less than 2 nm, for its function of strengthening adhesion between layers.

In general, some parts of the stack forming the coating can be doubled up in order to modulate or strengthen their effect. For example, it is possible to double up the first group of layers, and therefore to have for example an Au(substrate)/Si/Au/Si/Au stack, with or without interposed layers of Cr, at some or all of the interfaces, as described above. In such a structure, the thicknesses of the layers may be different for a given material, for example the thickness of the first layer of Si may be different from that of the second layer of Si. In addition, whether intentional or not, the second layer of Si may have a degree of residual oxidation different from the first. Similarly, it is possible to double up the second group of layers, and therefore to have for example a TiO₂/SiO₂/TiO₂/SiO₂ stack in place of TiO₂/SiO₂, or else a SiO₂/TiO₂/SiO₂/TiO₂/zapon stack in place of SiO₂/TiO₂/zapon.

The coating of the invention permits numerous combinations of layers, making it possible to obtain a wide range of colors and renderings, in particular colors in shades of red, purple, blue, green and also brown tones.

The table below gives some examples of layers produced, with the colors obtained. The luminosity L* and the chromaticity values a* and b* are evaluated in the space defined by the International Commission on Illumination, CIE L*a*b*, as indicated in “Technical Report of Colorimetry” CIE 15:2004. The measurements are performed in SCI (Specular Component Included) and SCE (Specular Component Excluded) modes and are presented below in SCI mode.

| | L*a*b* | | Thicknesses |
|---|---|---|---|
| Color | (SCI) | Stack | (nm) |
| Green | 43 / −14 / 15 | Au(substrate) / Si / Cr / | >100 / 35 / 3 / |
| | | Au / TiO₂ | 7 / 32 |
| Dark | 58 / −6 / 10 | Au(substrate) / Si / Au / | >100 / 39 / 34 / |
| green | | TiO₂ / SiO₂ | 17 / 41 |
| Light | 85 / 1 / 8 | Au(substrate) / Si / Au / | >100 / 29 / 25 / |
| blue | | SiO₂ / TiO₂ | 75 / 47 |
| Brown | 49 / 11 / 11 | Au(substrate) / Cr / Si / | >100 / 17 / 12 / |
| | | Au / TiO₂ | 15 / 8 |
| Light | 52 / 7 / 9 | Au(substrate) / Cr / Si / | >100 / 17 / 12 / |
| brown | | Cr / Au / Cr / TiO₂ | 3 / 14 / 3 / 6 |

In general, our approach makes it possible to obtain a very wide color panel through optical interference of light, and in particular to obtain a color other than black. Black can be defined as the colors having coordinates L*a*b* such that −2≤a*≤2 and −2≤b*≤2 and L*≤30.

FIGS. 1a to 1c schematically represent alternatives of a first embodiment of a coating according to the invention. In all these alternatives, the first group of the coating comprises the same structure of two layers of gold surrounding a layer of silicon. The first two alternatives comprise a second group composed of two oxide layers, respectively a layer of silicon dioxide SiO₂ and a layer of titanium dioxide TiO₂, the order of which is reversed in the second alternative. The third alternative in FIG. 1c has the same stack as the first alternative in FIG. 1a onto which a finishing layer of zapon is added.

FIGS. 2a and 2b schematically represent alternatives of a second embodiment of a coating according to the invention. According to the realization in FIG. 2a, the first group of the coating comprises a structure of two layers of gold surrounding a layer of silicon. The second group comprises an oxide layer, in this case a layer of titanium dioxide TiO₂, onto which a layer of zapon is added. FIG. 2b represents an alternative embodiment of the realization in FIG. 2a, in which a thin layer of chromium is interposed between each pair of adjacent successive layers of the realization in FIG. 2a, so as to increase adhesion between these layers.

Lastly, FIG. 3 schematically represents a third embodiment of a coating according to the invention. The first group includes three relatively thick layers of chromium respectively arranged on each of the three base layers of the first group, so as to provide an optical complement to the first group. In other words, the first layer forming the substrate comprises a thick layer of gold augmented by the overlaying of a layer of chromium, and the third layer of gold is augmented by its positioning between two layers of chromium. The second group is identical to that in the realization according to FIG. 1c.

The coating of the invention described above may be combined with other features contributing to a coloring effect or, more generally, to a decoration effect of the component. For example, the surface to be decorated of the component may comprise a surface structuring covered entirely or in part by the coating described above. This coating has a total thickness that is sufficiently small for it to follow and preserve the contours of the surface structuring. A surface structuring can consist for example of sunray-brushing, sandblasting, satin finishing, brushing, snailing, at least one côthe de Genève, circular graining, circling and/or any type of repeat-motif decoration.

The body can be made of numerous materials and in particular can be made of brass, gold, ceramic, especially zirconia or alumina, sapphire, silicon, nickel Ni, or nickel-phosphorus NiP. It can be a body made entirely of the same material or comprising a plurality of materials. In particular, the surface to be colored of the body may comprise a layer of material, for example to facilitate the realization of a surface structuring such as that mentioned above within its thickness. Such a layer may for example be a layer of silver.

The component may be a timepiece component, for example an exterior timepiece component such as a dial, a bezel, a bezel disk, a glass, a case, a bracelet, or a timepiece movement component, such as a mass or blank or bridge or barrel cover or stop click cover.

The invention also relates to a process for producing a timepiece component, especially an exterior timepiece component, especially a dial, comprising a prior step of producing a body of the timepiece component, wherein said process comprises depositing a coating onto at least part of a surface of said body, this depositing of a coating comprising the following steps:
depositing a first layer made of at least one metallic material;
depositing a second layer of semiconductor material;
depositing a third layer made of at least one metallic material;
optionally repeating the depositing of the second and third layers;
depositing one or more oxide layers;
optionally depositing an upper finishing layer such as an acrylic and/or nitrocellulose layer, especially a layer of zapon;
optionally depositing one or more layers of a metallic material, especially chromium or titanium, interposed between two of said layers of the coating defined above, such a layer of chromium having a very small thickness of less than or equal to 2 nm so as to promote adhesion of said two coating layers, or such a layer of chromium having a thickness greater than 2 nm so as to form a layer of partial absorption.

The depositing of the individual layers by the abovementioned steps is performed in the order indicated, the individual layers being overlaid one on top of the other, starting from the surface of the component body. These layers are therefore overlaid and adjoining, arranged in the order indicated, with the exception of any intermediate layers of metal, in particular layers of chromium, which may be interposed between these individual layers in accordance with the abovementioned optional deposition.

According to an advantageous embodiment, all or part of the layers of the coating are deposited by physical vapor deposition PVD, for example by vacuum evaporation or cathodic sputtering or by ion beam, by chemical vapor deposition CVD, or by atomic layer deposition ALD.

Moreover, and again advantageously, it is possible for all the layers of the coating to be deposited by the same technique in the same production cycle, aside from an upper finishing layer such as an acrylic and/or nitrocellulose layer, especially a layer of zapon, if present. These depositions are preferably made without venting between the deposition of two successive layers.

Alternatively, different deposition techniques may be used, including PVD, CVD and also ALD techniques, for different layers of the coating, provided they are compatible.

As a first implementation example of the production process, vacuum evaporation is used, which makes it possible to deposit thin layers of the elements Si, Cr, Au, TiO₂, and SiO₂ with very well controlled thickness. The semiconductor layer is in that case composed of Si, the metal layers of Au and optionally Cr, the optional adhesion layers of Cr, and the oxide layers of TiO₂ and SiO₂.

As a second implementation example of the production process, cathodic sputtering is used, which likewise makes it possible to deposit thin layers of the elements Si, Cr, Au, TiO₂, and SiO₂ with very well controlled thickness. The semiconductor layer is in that case composed of Si, the metal layers of Au and optionally Cr, the optional adhesion layers of Cr, and the oxide layers of TiO₂ and SiO₂.

As a third implementation example of the production process, cathodic sputtering is used, which makes it possible to deposit thin layers of TaOₓN_{y}, Cr, and Au with very well controlled thickness. The semiconductor layer is in that case composed of TaOₓN_{y}, the metal layers of Au and optionally Cr, the optional adhesion layers of Cr, and the upper layers of TaOₓN_{y}.

It is possible to use different embodiments of deposition techniques known to those skilled in the art. For example, Ar can be projected onto the components during deposition, thereby densifying the layers, according to the ion beam-assisted PVD technique. The same ion beam can also be fed with O₂ or N₂ to respectively promote oxidation and/or nitridation of the coating.

During the deposition, the characteristics of the deposited layers can be observed in a known manner. For example, a quartz crystal microbalance placed inside the deposition chamber allows the deposited thickness to be monitored with great accuracy. Similarly, it is possible for the optical transmission or optical reflection of the deposited layer to be analyzed during deposition, thereby making it possible to aim for an optical property target rather than a thickness target.

Specifically, the chambers of the deposition machines are placed under vacuum pressure during the deposition cycles. However, the residual atmosphere invariably contains residual gases such as O₂ or H₂O or N₂, which means that a certain degree of unintentional partial oxidation and/or nitridation of the layers is possible. This unintentional phenomenon can be minimized or even eliminated by preparing the deposition machine appropriately, especially by cleaning it. This partial oxidation and/or nitridation is likely to have an influence on the optical properties and therefore potentially on the overall rendering of the deposited coating. Where appropriate, it is possible to adjust the thicknesses of the layers to compensate for and eliminate this unintentional optical effect and to obtain the right rendering.

Measurements have shown that the Si semiconductor material deposited according to the invention has optical behavior close to pure unoxidized Si. Specifically, refractive index measurements in a “clean” machine (long pumping time) with a low residual oxygen partial pressure give a refractive index n of 4.04 for an incident wavelength of 550 nm and 3.87 for an incident wavelength of 630 nm, which is very close to the values for pure silicon (4.39 for amorphous silicon and 4.08 for crystalline silicon at 630 nm). In a “dirty” machine (shorter pumping time), the refractive index measurements are 3.35 for an incident wavelength of 550 nm and 3.20 for an incident wavelength of 630 nm, which is lower but still a long way from the value of 1.47 for silicon dioxide SiO₂. Similarly, the extinction coefficients k remain very high, and very much higher than 0.05 over a large part of the visible part of the spectrum. The Si-based material deposited by the process of the invention therefore always behaves as a semiconductor, irrespective of the state of the deposition machine and of the possible natural phenomenon of unintentional oxidation.

In summary, the above considerations show that it is therefore possible to implement the invention as described, based on a coating comprising a first group having a second layer of semiconductor material. This semiconductor material may have oxidation, in particular unintentional oxidation, which is either negligible or compensated for by adjusting the thicknesses of the coating layers in order to obtain the desired result, especially the desired color.

Finally, the invention has the advantage of simplifying the production process, especially through the use of a second layer of semiconductor material. Moreover, the semiconductor material provides advantageous optical properties: specifically, the semiconductor material has a high refractive index, is partially absorbing (extinction coefficient k>0.05 over a large part of the visible range), and is robust (it allows reproducible industrial deposition that is stable over time).

The invention has many other advantages. In addition to the reflection spectrum obtained, the durability of the stack, i.e. the constancy of the rendering over time, and also its production robustness (reproducibility from one production batch to the next, number of layers if possible low and thin thicknesses, deposition techniques if possible compatible, or even unique for the whole stack) are just as important.

It is also possible to list the following advantages of the invention:
Can be used in small and large production runs in an industrial and reproducible manner;
Stack of layers can be deposited in a simple manner in the same deposition equipment in the same cycle;
Strength and durability;
Numerous colors possible on the same basis, due to the multitude of influencing parameters;
Obtaining a target rendering, especially a target color, for example color according to the CIE L*a*b* reference, especially color different from black, or color outside the range defined by −2≤a*≤2 and −2≤b*≤2 and L*≤30;
Optimization over the entire visible range, and not just over a single wavelength or restricted range;
Little, if any, iridescence.

As mentioned above, it is possible to use an ultrathin layer of metal less than 2 nm in thickness, especially a layer of chromium or titanium, at at least one of the interfaces between two layers of a coating in order to promote adhesion between said two layers.

It is found that this effect is particularly remarkable for the adhesion of a finishing layer, such as an acrylic and/or nitrocellulose finishing layer, for example a layer of zapon, in order to promote the adhesion and/or robustness of this finishing layer. This approach could accordingly be implemented in all the embodiments envisaged by the invention. This approach can also be implemented in order to promote the adhesion and/or robustness of this finishing layer, irrespective of the type of layers and/or underlying structuring(s).

More generally, such a feature can be generalized to any finishing layer to be deposited on any coating on the surface of a component.

The invention accordingly also relates to a timepiece component, especially an exterior timepiece component, especially a dial, wherein it comprises a body, one surface of which is at least partially covered with a coating, wherein said coating comprises a finishing layer such as an acrylic and/or nitrocellulose finishing layer, especially a layer of zapon, and an intermediate layer on which this finishing layer is deposited that is composed of a metallic material, especially chromium or titanium, having a thickness of less than 2 nm, so as to promote the adhesion of said finishing layer.

The invention also relates to a process for producing a timepiece component, especially an exterior timepiece component, especially a dial, comprising a prior step of producing a body of the timepiece component, wherein said process comprises depositing a coating onto at least part of a surface of said body, this depositing of a coating comprising the following steps:
depositing a layer of a metallic material, especially chromium or titanium, having a thickness of less than or equal to 2 nm, then
depositing a finishing layer such as an acrylic and/or nitrocellulose finishing layer, especially a layer of zapon, directly on said layer of a metallic material, this finishing layer having improved adhesion due to said layer of metallic material.

The invention has been described on the basis of a coating that comprises a second group comprising one or more oxide layers. In all cases it is possible for each oxide layer of this second group to be replaced by a layer of a semiconductor material, in order to take advantage of the advantageous properties of a semiconductor material, as described above. Thus, according to one embodiment, the coating comprises a second group arranged on a first group as described, this second group comprising one or more layers of a semiconductor material, such as for example a layer of TaOₓN_{y}.

1. A timepiece component, wherein the timepiece component comprises a body, wherein a surface of the body is at least partially covered with a coating forming an optical coloring device,
wherein the coating comprises a stack of the following successive layers on the surface:
a first layer made of at least one metallic material;
a second layer of semiconductor material;
a third layer made of at least one metallic material;
optionally repetition of the second and third layers;
one or more oxide layers;
optionally, one or more layers of a metallic material, especially chromium or titanium, interposed between two others of the layers of the coating, wherein the one or more layers of the metallic material promote adhesion and/or partial absorption of light.

2. The timepiece component as claimed in claim 1, wherein
the first layer and/or the third layer is/are composed of a material having a refractive index in a visible range that comprises a real part of less than 3.5 and an extinction coefficient of greater than 1; and/or
the second layer is composed of a material having a refractive index in the visible range that comprises a real part of greater than 2.5 and an extinction coefficient of greater than 0.05; and/or
the one or more oxide layers is/are composed of a material having a refractive index in the visible range that comprises a real part of less than 3 and an extinction coefficient of less than 0.05.

3. The timepiece component as claimed in claim 1, wherein
the first layer has a thickness greater than or equal to 100 nm; and/or
the first layer is composed entirely of one or more metallic materials chosen from the group consisting of gold, platinum, titanium, palladium, chromium, rhodium, silver, copper, tungsten, and aluminum.

4. The timepiece component as claimed in claim 1, wherein
the second layer has a thickness of between 5 and 50 nm; and/or
the second layer is composed entirely of a semiconductor material chosen from the group consisting of silicon Si, germanium Ge, a combination of silicon Si and germanium Ge, and a III-V family semiconductor material.

5. The timepiece component as claimed in claim 1, wherein
the third layer has a thickness of between 2 and 50 nm; and/or
the third layer is composed entirely of one or more metallic materials chosen from the group consisting of gold, platinum, titanium, palladium, chromium, rhodium, silver, copper, tungsten, and aluminum.

6. The timepiece component as claimed in claim 1, wherein
the one or more oxide layers comprise two layers respectively composed of two different transparent materials, the two different transparent materials having refractive indices which are different, or
the one or more oxide layers comprise one or more layers of a material chosen from the group consisting of SiO₂, TiO₂, Al₂O₃, Si₃N₄, Ta₂O₅, TaOₓN_{y}, AlOₓN_{y}, and TiOₓN_{y}, or
the one or more oxide layers or the layers of semiconductor material comprise:
a layer of silicon oxide SiO₂ having a thickness in a range of from 40 to 140 nm, and/or
a layer of titanium oxide TiO₂ having a thickness in a range of from 5 to 100 nm,
optionally, a layer of chromium having a thickness of less than or equal to 2 nm being added to promote adhesion of one or more layers.

7. The timepiece component as claimed in claim 1, wherein
the timepiece component comprises at least one layer of a metallic material, having a thickness in a range of from 0.5 to 2 nm, arranged between two of the layers of the coating, in order to promote the adhesion of the two layers of the coating, and/or
the timepiece component comprises at least one layer of a metallic material, having a thickness greater than 2 nm, arranged between two of the layers of the coating, so as to form a layer of partial absorption modifying an optical behavior at an interface of the two layers of the coating.

8. The timepiece component as claimed in claim 1, wherein the timepiece component comprises a surface structuring performed on all or part of the surface of the body, the coating being at least partially arranged on the surface structuring and of sufficiently small thickness for the coating to follow and preserve contours of the surface structuring.

9. The timepiece component as claimed in claim 1, wherein
the body is made of one or more materials chosen from the group consisting of brass, gold, ceramic, sapphire, silicon, nickel Ni, and nickel-phosphorus NiP, and/or
the timepiece component is a dial, a bezel, a bezel disk, a glass, a case, a bracelet, or a timepiece movement component.

10. The timepiece component as claimed in claim 1, wherein the coating forms an optical coloring device of a color different from black, wherein black is defined as colors having the coordinates L*a*b*−2≤a*≤2 and −2≤b*≤2 and L*≤30.

11. The timepiece component as claimed in claim 1, wherein the coating comprises an upper finishing layer.

12. A timepiece, wherein the timepiece comprises a timepiece component as claimed in claim 1.

13. A process for producing a timepiece component, the process comprising
producing a body of the timepiece component, and
depositing a coating onto at least part of a surface of the body, wherein the depositing of the coating comprises:
depositing a first layer made of at least one metallic material;
depositing a second layer of semiconductor material;
depositing a third layer made of at least one metallic material;
optionally repeating the depositing of the second and third layers;
depositing one or more oxide layers;
optionally depositing an upper finishing;
optionally depositing one or more layers of a metallic material, interposed between two of the other layers of the coating, the one or more layers of the metallic material having a thickness of less than or equal to 2 nm, so as to promote adhesion of the two coating layers, or having a thickness greater than 2 nm, so as to form a layer of partial absorption.

14. The process as claimed in claim 13, wherein all or part of the layers of the coating are deposited by physical vapor deposition PVD, or by chemical vapor deposition CVD, or by atomic layer deposition ALD.

15. The process as claimed in claim 13, wherein all the layers of the coating, aside from an upper finishing layer, if present, are deposited by the same process in the same production cycle.

16. The process as claimed in claim 13, wherein process comprises measuring a thickness of a deposited layer and/or an optical transmission or optical reflection of a deposited layer during deposition, so as to determine an end of the deposition as a function of measurement(s) obtained in the measuring.

17. The timepiece component as claimed in claim 1, wherein the timepiece component is an exterior timepiece component.

18. The timepiece component as claimed in claim 1, wherein the timepiece component is a dial.

19. The timepiece component as claimed in claim 2, wherein the one or more oxide layers is/are composed of a material having a refractive index in the visible range that comprises a real part of less than 3 and an extinction coefficient of less than 0.01.

20. The timepiece component as claimed in claim 3, wherein the second layer is composed entirely of a semiconductor material which is gallium arsenide GaAs or tantalum oxynitride (TaOₓN_{y}).
